(19) United States
(12) Patent Application Publication
(10) Pub. No.: US 2005/0130408 A1
(43) Pub. Date: Jun. 16, 2005

(54) Method for forming metal wiring of semiconductor device

(76) Inventor: Il Young Yoon, Chungcheongbuk-do (KR)

Correspondence Address: LADAS & PARRY LLP, 224 SOUTH MICHIGAN AVENUE, SUITE 1200, CHICAGO, IL, 60604, US

(21) Appl. No.: 10/875,361

(22) Filed: Jun. 24, 2004

(30) Foreign Application Priority Data
Dec. 10, 2003 (KR) 2003-89289

(51) Int. Cl. H01L 21/44; H01L 21/4763

(52) U.S. Cl. 438/633

(57) ABSTRACT

Disclosed is a method for forming a metal wiring of a semiconductor device. After an oxide interlayer is formed on a lower layer including a metal layer pattern, a contact hole exposing an upper surface of the metal layer pattern is formed in the oxide interlayer. After filling the contact hole by forming a tungsten film on the oxide interlayer including the contact hole, the tungsten film is polished by performing a first CMP process until an upper surface of the oxide interlayer is not exposed. After performing the first CMP process, a second CMP process is performed in such a manner that the tungsten film only remains in the contact hole.

### BACKGROUND OF THE INVENTION

1. Field of the invention

The present invention relates to a method for forming a metal wiring of a semiconductor device, and more particularly to a method for forming a metal wiring of a semiconductor device through carrying out two-step tungsten CMP processes according to density an oxidizing agent included in tungsten slurry.

2. Description of the Prior Art

Generally, oxidizing agents mainly used in tungsten CMP slurry include H₂O₂, KlO₃, Fe(NO₃)₃, or H₅lO₆.

Hereinafter, a conventional method for forming a metal wiring by utilizing such oxidizing agents will be explained with reference to FIGS. 1A and 1B.

FIGS. 1A and 1B are sectional views showing process steps for explaining the conventional method for forming a metal wiring of a semiconductor device.

As shown in FIG. 1A, according to the conventional method for forming the metal wiring, after a metal layer pattern 13 is formed on a lower layer 11, an oxide interlayer 15 is deposited on the lower layer 11 including the metal layer pattern 13.

Next, after coating photoresist material on an upper surface of the oxide interlayer 15, an exposure and development process is carried out through a photolithography technique. Then, a resultant structure is selectively etched so that a photoresist film pattern (not shown) is formed.

Thereafter, the oxide interlayer 15 is selectively removed by utilizing the photoresist film pattern as a mask, thereby forming a contact hole 17 exposing an upper surface of the metal layer pattern 13.

Then, after forming a barrier layer 19 on a surface of the oxide interlayer 15 including the contact hole 17, a tungsten film 21 is deposited on the barrier layer 19 with a thickness enough to fill the contact hole 17, that is, with a thickness exceeding a height of the contact hole 17.

As shown in FIG. 1B, the tungsten film 21 is planarized by performing a CMP process for one time while utilizing an oxidizing agent widely used in above-mentioned tungsten CMP slurry, such as H₂O₂, KlO₃, Fe(NO₃)₃, or H₅lO₆. At this time, as shown in FIG. 1B, when a planar process is carried out, a recess 23 is formed at a tungsten film 19a remaining in the contact hole 17.

However, according to the conventional technique, the oxidizing agent used for the tungsten CMP process may oxidize tungsten in order to increase a polishing rate.

Accordingly, when the tungsten CMP process is performed with slurry including a little amount of oxidizing agents, polishing time is lengthened.

In contrast, when the tungsten CMP process is performed with slurry including a great amount of oxidizing agents, side effects, such as a contact recess, a dishing, and oxide erosion, may occur.

### SUMMARY OF THE INVENTION

Accordingly, the present invention has been made to solve the above-mentioned problems occurring in the prior art, and an object of the present invention is to provide a method for forming a metal wiring of a semiconductor device capable of reducing a contact recess, a dishing, and oxide erosion through carrying out two-step CMP processes by using slurry including a first oxidizing agent having high density and by using slurry including a second oxidizing agent having low density, respectively.

In order to accomplish this object, there is provided a method for forming a metal wiring of a semiconductor device, the method comprising the steps of: forming a metal layer pattern on a lower layer; forming an oxide interlayer on the lower layer including the metal layer pattern; forming a contact hole exposing an upper surface of the metal layer pattern in the oxide interlayer; filling the contact hole by forming a tungsten film on the oxide interlayer including the contact hole; polishing the tungsten film by performing a first CMP process until an upper surface of the oxide interlayer is not exposed; and performing a second CMP process after the first CMP process in such a manner that the tungsten film only remains in the contact hole.

According to the preferred embodiment of the present invention, density of oxidizing agent of slurry used in the first CMP process is about 5˜20 wt %.

A density of oxidizing agent of slurry used in the second CMP process is about 0.1˜3 wt %.

A thickness of the tungsten film remaining in the upper surface of the oxide interlayer in the first CMP process is about 300˜1,000 Å.

The oxidizing agent used in first and second CMP processes is one selected from the group consisting of H₂O₂, KlO₃, Fe(NO₃)₃, and H₅lO₆.

### BRIEF DESCRIPTION OF THE DRAWINGS

The above object, features and advantages of the present invention will be more apparent from the following detailed description taken in conjunction with the accompanying drawings, in which:

FIGS. 1A and 1B are sectional views showing process steps for explaining a conventional method of forming a metal wiring of a semiconductor device;

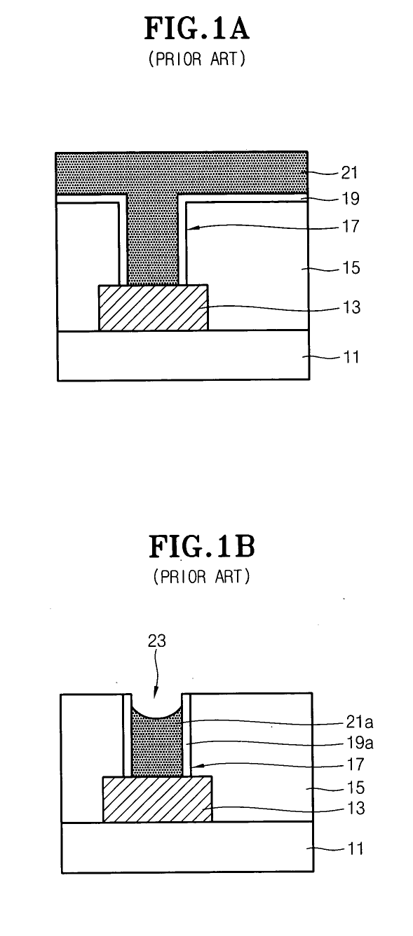

FIGS. 2A to 2C are sectional views showing process steps for explaining a method of forming a metal wiring of a semiconductor device according to one embodiment of the present invention; and

FIG. 3 is a graph view showing a removal rate for a tungsten layer according to density of H₂O₂ in a method for forming a metal wiring of a semiconductor device according to one embodiment of the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

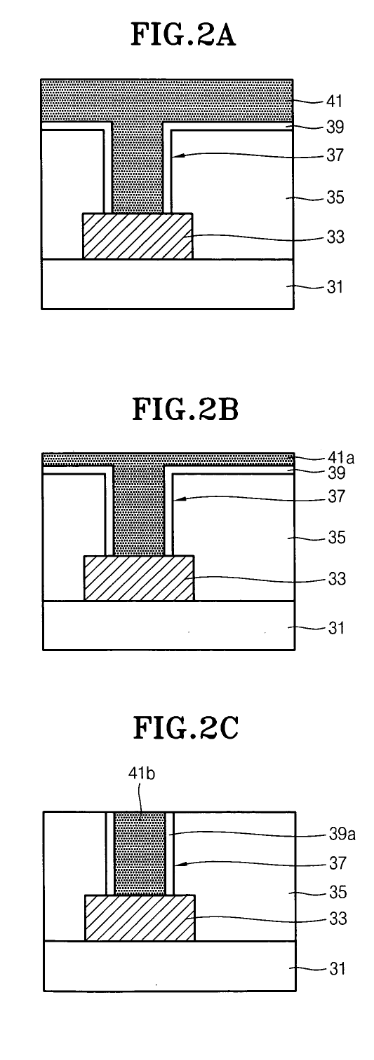

FIGS. 2A to 2C are sectional views showing process steps for explaining a method of forming a metal wiring of a semiconductor device according to one embodiment of the present invention.

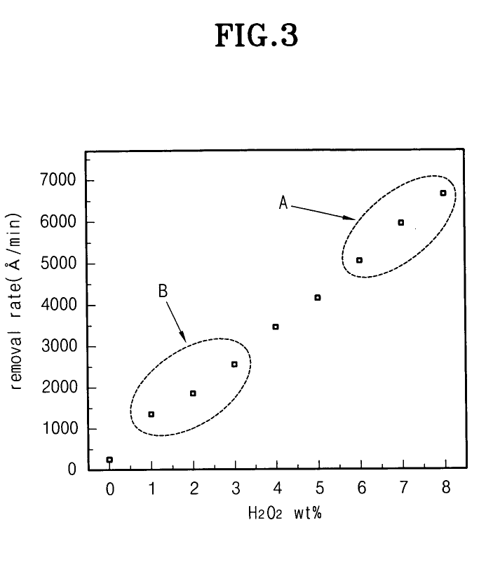

FIG. 3 is a graph view showing a removal rate for a tungsten layer according to density of H₂O₂ in a method for forming a metal wiring of a semiconductor device according to one embodiment of the present invention.

As shown in FIG. 2A, according to the method for forming the metal wiring of the semiconductor device of the present invention, after forming a metal layer pattern 33 on a lower layer 31, and an oxide interlayer 35 is deposited on the lower layer 31 including the metal layer pattern 33.

Next, after coating a photoresist material on the oxide interlayer 35, an exposure and development process is carried out through a photolithography technique. Then, a resultant structure is selectively etched, thereby forming a photoresist film pattern (not shown).

Thereafter, the oxide interlayer 35 is selectively removed by utilizing the photoresist film pattern as a mask in order to form a contact hole 37 exposing an upper surface of the metal layer pattern 33.

Then, after forming a barrier layer 39 on a surface of the oxide interlayer 35 including the contact hole 37, a tungsten film 41 is deposited on the barrier layer 39 with a thickness enough to fill the contact hole 37, that is, with a thickness exceeding the height of the contact hole 37.

Next, as shown in FIG. 2B, the tungsten film 41 is planarized by performing two-step CMP processes. At this time, a first CMP process is performed by utilizing slurry including a first oxidizing agent having high density, such as H₂O₂, KlO₃, Fe(NO₃)₃, or H₅lO₆, thereby planarizing the tungsten film 41 in such a manner that the tungsten film 41 has a predetermined thickness. At this time, as is understood from an “A” portion shown in FIG. 3, density of the oxidizing agent included in slurry used for the first CMP process is about 5˜20 wt %. In addition, it is preferred to determine a polishing time by considering an etching rate when the first CMP process is performed. In addition, when the first CMP process is performed, a polishing target must be set in such a manner that a polishing process has been finished when the tungsten film formed on the oxide interlayer 35 has a thickness of about 300˜1000□.

Then, as shown in FIG. 2C, a second CMP process is additionally performed by utilizing slurry including a second oxidizing agent having low density, such as H₂O₂, KlO₃, Fe(NO₃)₃, or H₅lO₆, thereby completely polishing tungsten film parts remaining in predetermined regions expect for the contact hole 37. At this time, as is understood from a “B” portion shown in FIG. 3, density of the oxidizing agent included in slurry used for the second CMP process is about 0.1˜3 wt %.

As described above, according to the method for forming the metal wiring of the semiconductor device of the present invention, two-step tungsten CMP processes are performed by using two kinds of slurry having first and second oxidizing agents, which have mutually different densities, in order to maintain a high polishing rate. Accordingly, the present invention can reduce a contact recess, dishing, and oxide erosion as compared with the conventional technique without lowering the polishing rate.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for forming a metal wiring of a semiconductor device, the method comprising the steps of:
i) forming a metal layer pattern on a lower layer;
ii) forming an oxide interlayer on the lower layer including the metal layer pattern;
iii) forming a contact hole exposing an upper surface of the metal layer pattern in the oxide interlayer;
iv) filling the contact hole by forming a tungsten film on the oxide interlayer including the contact hole;
v) polishing the tungsten film by performing a first CMP process until an upper surface of the oxide interlayer is not exposed; and
vi) performing a second CMP process after the first CMP process in such a manner that the tungsten film only remains in the contact hole.

2. The method as claimed in claim 1, wherein a density of oxidizing agent of slurry used in the first CMP process is about 5˜20 wt %.

3. The method as claimed in claim 1, wherein a density of oxidizing agent of slurry used in the second CMP process is about 0.1˜3 wt %.

4. The method as claimed in claim 1, wherein a thickness of the tungsten film remaining in the upper surface of the oxide interlayer in the first CMP process is about 300˜1,000 Å.

5. The method as claimed in claim 1, wherein the oxidizing agent used in first and second CMP processes is one selected from the group consisting of H₂O₂, KlO₃, Fe(NO₃)₃, and H₅lO₆.

6. The method as claimed in claim 1, further comprising a step of forming a barrier layer on the oxide interlayer including the contact hole, before the tungsten film is deposited.
